(19) United States
(12) Patent Application Publication
(10) Pub. No.: US 2008/0305349 A1
(43) Pub. Date: Dec. 11, 2008

(54) Energy-curing breathable coatings (combined)

(75) Inventor: Steven Nahm, Loveland, OH (US)

Correspondence Address: DICKSTEIN SHAPIRO, 1177 AVENUE OF THE AMERICAS (6TH AVENUE), NEW YORK, NY, 10036-2714, US

(73) Assignee: SUN CHEMICAL CORPORATION

(21) Appl. No.: 11/806,977

(22) Filed: Jun. 5, 2007

(51) Int. Cl. B32B 9/04; B32B 27/00; C23C 14/28; C23C 14/30

(52) U.S. Cl. 428/500; 427/595; 427/596; 428/411.1

(57) ABSTRACT

Durable, breathable energy curable coatings for substrates. The films are obtained by applying a suitable single phase aqueous coating composition to a substrate and then applying a high energy curing, i.e., ultraviolet or electron beam curing, to the composition to form a durable multiphase solid film, having hydrophilic and hydrophobic domains.

### BACKGROUND OF INVENTION

Coatings which impart resistance to liquid water penetration while permitting transmission of water vapor through a substrate which has no inherent barrier properties of its own are desirable. There are two major technologies that perform this function. Monolithic coatings, films and membranes are continuous and free of purposeful voids connecting the two sides. They function by the absorption of water into the film, diffusion of the water through the film, and evaporation of water from the other side, which is driven by a concentration gradient across the film. Microporous coatings, films and membranes are also continuous but contain an extensive interconnecting network of voids that connect the two sides with a continuous air path. Such microporous membranes permit passage of water vapor but hold out liquid water primarily by controlled low surface tension such that liquid water does not readily wet the inside surfaces of the void network. Under suitable pressure, liquids can be forced through the voids of microporous films while no liquid penetration through a monolithic film is possible unless the pressure is sufficient to cause film rupture. Among the applications where this combination of characteristics is useful are durable goods such as coats, hats, shoes and gloves which protect the wearer against outdoor environments such as rain, snow, wind and the like, or as a layer in garments worn during recreational or athletic activities such as hunting, fishing, or team sports or in hazardous environments such as encountered by emergency response workers to protect against extreme temperatures, chemical or biological agents where the breathable feature provides a level of enhanced comfort for the wearer. Other examples include disposable garments or coverings such as those found in medical treatment facilities including, for instance, surgical gowns and gloves, bed and shoe coverings, as well as personal hygiene applications such as diapers and wound dressings, transdermal delivery systems, and the like. Other applications include food packaging, particularly for fruits and vegetables, permanent building and construction applications such as external house wraps, roof membranes, exterior wood coatings and internal wall coverings, or structures used for temporary storage or weather protection such as tarps, tents and sleeping bag covers and the like, and fabrics used in luggage or as automotive and furniture upholstery, and the like.

Numerous approaches to providing breathable coatings have been described in the prior art. One approach involves curable linear polyurethane di(meth)acrylates, such as, for example, described in U.S. Pat. Nos. 4,751,133, 4,727,868, 4,638,043, 4,614,787 and 4,483,759, which rely on solutions of relatively high molecule weight linear molecules having reactive (meth)acrylate terminal groups and which contain hydrophilic segments as part of their main chain backbone structure, dissolved in inert volatile organic solvents for application to a substrate. They are crosslinked through their terminal (meth)acrylate functional groups by a free radical process after evaporation of the inert solvent present. In the absence of solvent, these compositions generally have viscosities which are too high for convenient application directly to substrates under ambient conditions. Similarly, U.S. Pat. No. 4,097,439 discloses mixtures of linear high molecular weight polyurethanes containing terminal unsaturation in combination with acrylate monomers applied to substrates as solutions in volatile solvents. Also, U.S. Pat. No. 4,323,639 discloses mixtures of related high molecular weight linear polyether amides containing terminal unsaturation in combination with acrylate monomers dissolved in inert solvent. Interestingly, neither of these disclosures recognizes the utility of their compositions in breathable applications.

Another approach, which still requires solvent removal, is the generation of breathable microporous membranes directly from low viscosity solutions by an in situ photopolymerization/precipitation process as described for example in U.S. Pat. Nos. 4,466,931 and 5,126,189. However, the use of volatile solvents presents substantial health, safety and environmental issues which require expensive mitigation efforts, including the need for their removal prior to initiating cure, and the need to recover or otherwise handle the evolved organic volatiles in an environmentally responsible manner.

One approach to avoid problems due to high viscosity and use of solvent involves the formation of breathable coatings and membranes by extrusion directly onto the substrate or onto a temporary carrier film before transfer and lamination to the substrate. This is described, for instance, in U.S. Pat. No. 6,432,547. Drawbacks to this approach include the expense and difficulty in accurately controlling and maintaining low film weights, producing such thin films in a defect free manner, the need to handle molten polymer compositions and for adjusting molten polymer rheology for extrusion, the potential for damaging the extruded membrane during lamination to the substrate when not extruded and laminated in line, the possible need for the use of a carrier film to facilitate handling the functional membrane without damage, as well as disposal and recycling of the carrier, the frequent need for a separate adhesive interlayer which is also required to be breathable, poor adhesion of the extruded film, coating or membrane to the support due to its limited contact with the substrate, mechanical damage in use, and other problems related to molten polymer flow, substrate wetting and adhesion. Such limited flow and wetting of the substrate surface is illustrated for an extrusion coating in FIG. 1. If the film is not used in a laminated structure, it requires exceptional strength or protection from damage for unsupported use. Such unsupported films or membranes are generally much thicker than coatings, requiring use of more material which is not only more expensive but also reduces their breathability.

Theoretically, the most benign volatile solvent is water but use of water as a solvent for breathable compositions can lead to other difficulties, such as extensive swelling of the cured films during use. Consequently, breathable coatings have been applied as aqueous dispersions, such as described in U.S. Pat. Nos. 4,818,600 and 6,897,281. As illustrated in FIG. 2, such dispersion coatings reside almost entirely on the surface of porous substrates such as fabrics due to the limited penetration of the dispersed resin particles into the fabric—they are essentially filtered out by the small spaces between fibers and threads. In addition, dispersion coatings require heating to dry the coatings and to coalesce them into a strong, continuous and defect free film, and as the applied coating weights are increased, these compositions require longer residence times (reduced line speeds) or if web speeds are increased, they require longer path lengths through the dryer (larger dryer footprint) because of upper drying temperature limitations imposed by the substrates. The durability of such surface coatings also depends on their ability to wet the substrate and their adhesion to it. Furthermore, because these dispersion coatings are almost entirely confined to the fabric surface, and as with breathable laminates, they are also susceptible to damage through mechanical abrasion and delamination in use.

Still another approach involves vacuum vapor deposition of coating precursor monomers onto various substrates followed by cure under UV, EB or plasma fields, such as described in U.S. Pat. No. 6,660,339. The materials useful in this approach are limited to a relatively short list of volatile monomers which have their own associated health, safety and environmental hazards.

It is therefore desirable to provide a new approach to durable films with breathability and liquid barrier properties that overcomes the problems introduced by high levels of volatile solvents to reduce the viscosity to easily coatable levels, addresses the performance and durability issues arising from dispersion and extrusion coatings which are located substantially on the substrate surface, and avoids the limited range and hazardous nature of volatile materials which may be used for vacuum deposition/in situ polymerization techniques.

### SUMMARY OF THE INVENTION

The present invention provides durable, breathable energy curable coatings for substrates and articles made from these coated substrates. The films are obtained by applying a suitable single phase liquid coating composition to a substrate and then curing by applying a high energy radiation, i.e., ultraviolet or electron beam, to the liquid composition to form a durable multiphase solid film, having separate hydrophilic and hydrophobic regions, and which is characterized by a water vapor transmission rate of at least 500 g/m²/day when the cured film has film weights of about 45 g/m² or less and which does not substantially swell or absorb liquid water such that the coating durability is not substantially reduced by prolonged contact with liquid water. The suitable single phase liquid coating composition is comprised of water and one or more components that are curable by high energy radiation, such components being comprised of materials with a range of molecular weights particularly including curable materials of low molecular weight and may include additional reactive materials with intermediate and high molecular weights, and may also contain components that are substantially unchanged by the high energy radiation where such essentially inert and soluble materials are higher in molecular weight than at least a portion of the curable components. Such compositions can be applied at ambient temperatures, e.g., about 20-25° C., and can be cured without evolution of volatile organic solvents to yield durable breathable coatings whose durability is enhanced by saturation into the substrate, creating a fiber reinforced composite type of structure as illustrated in FIG. 3. Such coatings can be applied at lower film weights and remain durable because the bulk of the coating is actually protected from mechanical damage in use by the fibers of the substrate.

In one preferred embodiment, the curable composition contains higher molecular weight components which are participating resins or polymers in which reactive (curable) groups are preferably present as end groups of a branch or side chain originating from the main backbone of the resins or polymers, the reactive end groups forming a graft or copolymer network with curable lower molecule weight components present, and which may further contain hydrophilic or hydrophobic groups, preferably having both hydrophilic and hydrophobic groups, which groups are preferably located in the branches or side chains, particularly at or near the ends of said side chains. Such participating branched resins or polymers contain on average at least three end groups per molecule. The curable lower molecular weight components present may similarly contain either or both hydrophilic and hydrophobic segments. The reactive groups in the composition can be the same or different and can cure by the same or different reaction mechanisms.

In a second preferred embodiment, the curable composition contains higher molecular weight components which do not substantially react to form a graft or copolymer network with the lower molecular weight curable components and are therefore “spectator” resins or polymers but which preferably may become entangled and entrapped within a crosslinked network formed by the radiation cured components. Such spectator materials may comprise a mixture of components, each of which may comprise either or both hydrophilic and hydrophobic segments. The lower molecular weight curable components present may also comprise a mixture of components which separately contain either or both hydrophilic and hydrophobic segments. The spectator resins or polymers are preferably branched and contain the hydrophilic and hydrophobic segments in the branches or side chains. Here also, the curable lower molecular weight components may react by one or more than one mechanism, such as combination of radical or cationic mechanisms, whereby the spectator resins or polymers contain groups that will not substantially participate in the cure reactions of the lower molecular weight components present but which may react with themselves by a different reaction mechanism.

In yet another preferred embodiment, the higher molecular weight coating material contains reactive groups and may be an oligomer and therefore have a molecular weight below about 5,000 daltons. Again, the curable groups may react by a single mechanism or a combination of mechanisms.

In all of these embodiments, the components of the coating composition combine to form a single liquid phase. The amount of water can be varied to assist in controlling coating viscosity as long as the amount is not sufficient to cause a phase separation wherein one phase is substantially aqueous and the other is substantially nonaqueous.

The liquid coating compositions can be applied to substrates by any convenient method including transfer and offset methods, where they may saturate porous substrates through their entire thickness or only saturate a fraction of the thickness, but they will be substantially absorbed into the pores and interstices of a porous substrate, and are then cured to a solid by exposure to high energy radiation from ultraviolet light or electron beam sources, or possibly by high frequency plasma discharge, particularly without the prior drying or purposeful and substantial removal of water. In the case of free radical curing under exposure to ultraviolet radiation, the coating composition generally includes free radical photoinitiators which interact with the incident ultraviolet radiation to generate initiating radical species. In the case of a cationic cure, cationic photoinitiators which interact with the incident radiation to generate the initiating cationic species are generally present. The coating compositions can optionally include other additives as typically found in coating applications such as colorants, rheological modifying agents, stabilizers and preservatives for the purpose of enhancing specific attributes of the liquid or cured product, such as application, performance, or appearance characteristics, and the like. Such other components, particularly colorants, reinforcements, and rheology modifiers, may be present as a separate finely dispersed solid phase or mixture of solid phases.

### BRIEF DESCRIPTION OF THE DRAWINGS

FIG. 1 illustrates the limited flow and wetting of a substrate surface by an extrusion coating.

FIG. 2 shows prior art dispersion coatings residing almost entirely on the surface of porous substrates due to the limited penetration of the dispersed resin particles into the fabric.

FIG. 3 shows durable breathable coatings whose durability is enhanced by saturation into the substrate creating a fiber reinforced composite type structure.

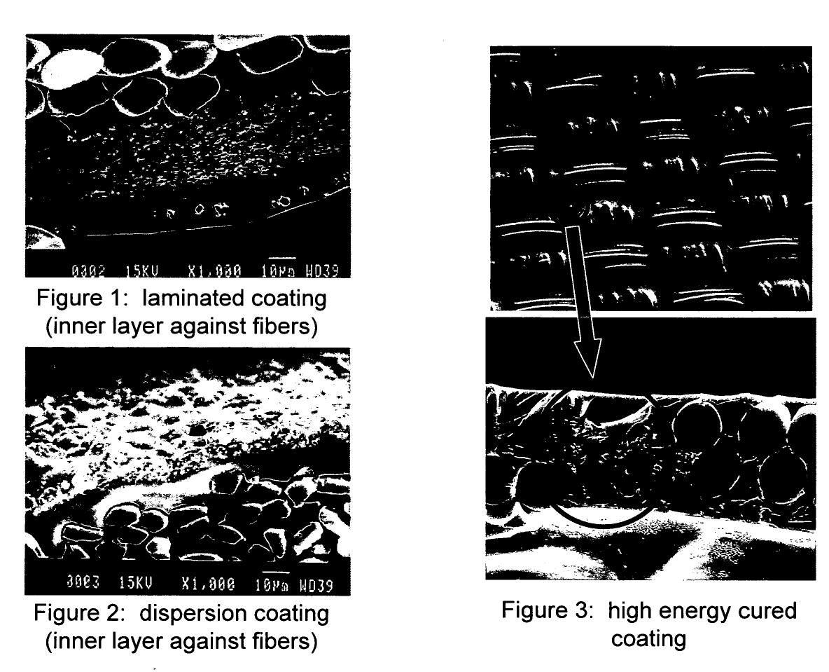

### DETAILED DESCRIPTION OF THE INVENTION

In accordance with the present invention, a monolithic durable and breathable liquid water resistant film is formed on a substrate by applying a liquid coating composition to the substrate and then curing the composition to a solid film with high energy radiation (ultraviolet or electron beam). The high energy curing preferably converts a single phase solution to a solid polymerized monolithic coating which has become micro phase separated. While not wanting to be bound by theory, it is believed that the best embodiments result in micro phase separations that form hydrophilic and hydrophobic domains which are co-continuous. The continuous hydrophobic domains are thought to provide mechanical strength and durability to the cured film, and the continuous hydrophilic domains are thought to provide an uninterrupted pathway for the efficient diffusion of water vapor through the film, and are responsible for the breathability. The liquid and cured coatings may contain one or more dispersed solid phases, the presence of which may modify the rheological properties of the uncured coating or provide color or reinforcement to the final cured coating. The coating composition is not, however, a “dispersion coating” composition as that term is used in the art, i.e., a dispersed resin phase in a continuous carrier phase.

The uncured coating composition is a single phase liquid solution comprised of water and dissolved coating materials, and optionally other components present to enhance or modify uncured or cured coating properties, a portion of which may be present as a dispersed solid phase, where all or only a portion of the soluble coating materials may be co-reactive under high energy radiation and where the composition also contains up to about 25% water by weight, more preferably from about 1% to about 20% by weight of water, and most preferably from about 3% to about 15% water. A portion of the energy curable coating materials contain hydrophilic segments and a portion of the coating materials contain hydrophobic segments, such that individual components within the mixture may contain either hydrophilic or hydrophobic types of segments, or both. Further, all or only a portion of the coating materials may be co-reactive under high energy irradiation.

Without being bound by theory, in addition to the combination of soluble components containing hydrophilic and hydrophobic segments which are incompatible in the solid (cured) state, the water is believed to provide two important functions. Not only does it function to reduce the viscosity of the liquid coating prior to cure, but it is believed to be an important component in driving the preferred co-continuous phase structure in the cured film. Consequently, it is a key provision of this invention that the single phase liquid coating composition be exposed to high energy radiation and cured on the substrate without substantial reduction of the water content through a purposeful drying step.

The relative amounts of the soluble coating components can be varied as desired as long as the liquid portion of the coating composition is a single phase solution which on curing micro phase separates to preferably form co-continuous hydrophilic and hydrophobic domains and is a durable, breathable, liquid water resistant film. The micro phase separated hydrophilic and hydrophobic domains may not possess sharp phase boundaries nor must they be visible to the naked eye or under visible light microscopy are preferably separated by molecule scale gradients of varying hydrophilic and hydrophobic balance. The presence of the preferred co-continuous micro phase structure may be implied by a sudden and large step change in breathability over a small compositional change, as illustrated, for instance in Table 3 below, where the compositional change is insufficient to cause a classic phase inversion such that the hydrophilic phase becomes continuous and the hydrophobic phase becomes discontinuous. Breathable means that the film at a cured film weight of about 45 g/m² or less has a water vapor transmission rate of at least 500 g/m²/day when measured at about 25° C. and about 75% relative humidity, and more preferably at least about 1,000 g/m²/day at a cured film weight of about 40 g/m² or less. Liquid water resistant means that the film is durable and does not pass liquid water and does not substantially swell or absorb liquid water on prolonged contact. Adequate water resistance and durability depend on end use application requirements, and are influenced by a number of factors, including cured film crosslink density, composition, thickness and adhesion to the substrate. There is no universally agreed upon standard for water resistance, or even the best method to assess durability, but it is conveniently assessed by “water double rubs”, a procedure in which a coated substrate contacting liquid water is rubbed with a minimally abrasive material such as a cotton swab or the like under consistent and standardized pressure. A pass or fail rating is determined by the number of back and forth rubs required to damage the coating, typically taken as the number of rubs to break through the coating to the substrate. While the minimum number of rubs will vary according to the particular end use application, adequate water resistance in this context may be considered to exceed about 20 double rubs at a film weight of about 10 g/m² before failure. To obtain adequate cured coating water resistance and durability, the combined concentration of all energy curable groups will typically be greater than about 1.5 millimoles per gram of the liquid portion of the coating, frequently greater than about 2.0 millimoles per gram and most often greater than about 2.5 millimoles per gram of the liquid portion of the coating on a water-free basis and excluding any solids that may be present as coating modifiers (such as rheology, color and/or mechanical property modifiers). The actual reactive group concentration required depends on the coating composition, and some covalent chemical bonds may be replaced by hydrogen or ionic bonds.

The coating materials generally comprise a mixture of compounds which individually have a range of molecular weights and number of curable groups per molecule. These mixed coating materials may conveniently be characterized as being higher and lower molecular weight materials, where the lower molecular weight materials may generally be referred to as “reactive diluents”, or alternatively, as monomers or lower oligomers, while the higher molecular weight materials may generally be referred to as resins or polymers, where the resins may alternatively be referred to as higher oligomers. Reactive diluents are generally and operationally defined as having molecular weights less than about 2,000 daltons, preferably less than about 1,000 daltons, and/or viscosities less than about 1,000 centipoises at ambient temperature (about 20-25° C.) and preferably less than about 500 centipoises, and containing four or fewer reactive groups per average molecule, while the higher oligomers are generally and operationally defined as having higher molecular weights, typically up to about 5,000 daltons, higher viscosities, typically up to about 15,000 centipoises at ambient temperature, and at least 2 reactive functional groups per average molecule. Resins are generally and operationally defined as having still higher molecular weights, typically above about 5,000 daltons, still higher viscosities, including being friable solids at ambient temperature, and preferably containing at least 2 reactive functional groups on each molecule while polymers are generally and operationally defined as having even higher molecular weights and are more frequently solid at ambient temperature, and may or may not have a number of reactive functional groups on each molecule.

The reactive diluents have at least one, and preferably at least two but generally no more than about four, curable (polymerizable) groups per average molecule, such that their reactive group concentration is less than about 12 millimoles per gram when taken separately and in the absence of other components, and preferably less than about 10 millimoles per gram when considered by themselves, which groups may preferably be reactive by free radical or cationic mechanisms. Suitable reactive diluents may be hydrophilic and may be water soluble and may also be used in combination with reactive diluents which are not substantially hydrophilic or water soluble as long as the final combination forms a single liquid phase solution. The ultraviolet or electron beam curable groups in these components include, but are not limited to, acrylate, methacrylate, allyl, three membered ring cyclic ethers (epoxides), four membered ring cyclic ethers (oxetanes), particularly hydroxyl group containing oxetanes such as trimethylolpropane oxetane, cyclic carbonates, particularly hydroxyl group containing cyclic carbonates such as glycerin carbonate, vinyl ethers, conjugated C═C groups such as those present in sorbate and drying oil esters, and the like. Suitable reactive diluents include, but are not limited to, polyethylene and polypropylene glycol di(meth)acrylates, (ethoxylated or propoxylated) hexanediol di(meth)acrylates, (ethoxylated or propoxylated) neopentyl glycol di(meth)acrylates, (ethoxylated and propoxylated) trimethylolpropane tri(meth)acrylates, (ethoxylated and propoxylated) glycerol tri(meth)acrylates, (ethoxylated and propoxylated) pentaerythritol tri and tetra(meth)acrylates, β-carboxyethyl acrylate, dimethylaminoethyl(meth)acrylate, diallyl phthalate, diethyleneglycol divinyl ether, sorbic acid and its esters including hydroxyethyl sorbate, ethylene glycol diglycidyl ether, 1,2- and 1,3-propanediol diglycidyl ether, 1,2-, 1,3-, 2,3- and 1,4-butanediol diglycidyl ether, (ethoxylated and propoxylated) trimethylolpropane triglycidyl ether, sorbitol polyglycidyl ether, and the reaction products of such polyol polyglycidyl ether-containing reactive diluents with unsaturated acids like (meth)acrylic acid, β-carboxyethyl acrylate, sorbic acid, vinyl sulfonic or vinyl phosphonic acid and the like.

In those instances where the curable coating composition contains components with ionogenic groups, the curable composition preferably contains components with complimentary incipient charge centers in approximately equal molar amounts. For example, an acidic diluent like β-carboxyethyl acrylate is best combined with an approximately equal molar quantity of a basic diluent like dimethylaminoethyl(meth)acrylate, while an acidic polymer like carboxymethyl cellulose is best when combined with approximately equal molar quantity of dimethylaminoethyl(meth)acrylate, and a basic polymer like polyethylene imine is best when combined with approximately equal molar quantities of β-carboxyethyl acrylate, and the like. Also useful curable ionomeric materials include the salts of multivalent metals with (meth)acrylic acid such as calcium or zinc diacrylate.

The curable groups present in the composition can all cure by the same mechanism or by multiple mechanisms as long as the mixed reactive functional groups present do not interfere with the polymerization of other reactive functional groups present. Such a disfavored combination includes the use of dimethylaminoethyl(meth)acrylate with groups curing under cationic catalysis like vinyl ethers. Additionally, use of reactive diluents containing only one reactive group per molecule should be limited to not more than about 25 mole percent of the reactive groups present in the composition in order to generate well crosslinked networks of the type that provides acceptable durability.

In addition to the reactive diluents, other components may be used that preferably have molecular weights greater than those of the reactive diluents. Further, these additional soluble components may contain one or more ultraviolet or electron beam curable groups or types of groups. These other soluble components may be oligomeric, i.e., having an average molecular weight up to about 5,000 daltons, or have a greater molecular weight and be a resin or polymer. These other soluble components may be participating or spectator materials, that is, they may or may not interpolymerize with the lower molecular weight reactive diluents. Preferably, at least a portion of the other soluble components contain one or more hydrophilic segments, one or more hydrophobic segments, or a combination of hydrophilic and hydrophobic segments within their molecular structures.

When the higher molecular weight components are co-reactive “participating” materials, they are preferred to be higher oligomers, resins or polymers which are branched and thus contain an average of at least 3 end groups per molecule, and preferably also contain hydrophilic segments or hydrophobic segments or both hydrophilic and hydrophobic segments within their branches, preferably near or at the ends of the branches and preferably but not exclusively where each type of segment is contained within a separate branch. The most preferred structures are highly branched and also contain reactive groups near or at the ends of a preponderance of the branches. Branches containing reactive end groups may also be characterized as hydrophilic or hydrophobic, and if both types of branches are present within the same molecule, either or both may contain reactive end groups. Mixtures of such reactive oligomers, resins or polymers can be employed. Their curable groups can comprise functionalities that react by one or more than one mechanism, such as combinations of both radical and cationic mechanisms, a so-called dual cure composition, whereby the reactive end groups in the oligomers, resins or polymers can participate in at least one such type of curing reaction involving reaction of the reactive diluent functional groups.

The most preferred reactive end groups of the branched participating oligomers, resins or polymers react by free radical initiated reactions, with acrylate being most preferred. Other reactive C═C containing structures include, but are not limited to, methacrylate, (meth)acrylamide, maleate, fumarate, sorbate, allyl, or residues derived from drying oil fatty acids by, for example, transesterification in whole or part of a branched polyol with drying oils such as linseed oil, such polyols preferably containing at least three hydroxyl groups in their structure, such as but not limited to glycerin, pentaerythritol, sorbitol, and the like, which may or may not be further modified with for example polyether segments such as polyethylene or polypropylene glycol. In the case of free radical initiated reactions, the reactive end groups of the branched participating oligomers, resins or polymers do not have to be capable of forming a crosslinked network in the absence of the reactive diluent. Such reactive end groups include maleate and fumarate or other groups which do not homopolymerize but do copolymerize with, for example, acrylate or vinyl ether groups. Another class of reactive end groups on the branched participating oligomers, resins or polymers which participate in cationic initiated reactions includes 3 or 4 membered ring cyclic ethers such as represented by cyclohexene oxide (fused ring epoxides), glycidyl (linear epoxides), and oxetane structures, as well as cyclic carbonates. Other members of this class include vinyl ether, hydroxyl and carboxyl end groups. In the case of cationic initiated reactions also, the reactive end groups of the branched participating oligomers, resins or polymers do not have to be capable of forming a crosslinked network in the absence of the reactive diluent. Such reactive end groups include hydroxyl and carboxyl groups which do not homopolymerize but which can copolymerize with for example, epoxy or vinyl ether groups.

The most preferred branched participating oligomers, resins or polymers can be classified as polyurethane acrylates but which can also contain reactive C═C groups such as methacrylate and (meth)acrylamide. The most preferred polyurethane acrylates are oligomers or resins of relatively low molecular weight such that at least about 90 weight percent of the material as characterized by a gpc curve against polystyrene standards is less than about 20,000 daltons, with a peak molecular weight between about 1,000 to 12,000 daltons, most preferably between about 1,500 and 5,000 daltons The most preferred polyurethane poly(meth)acrylates or poly(meth)acrylamides are made from branched polyisocyanates containing, on average, at least three isocyanate groups per molecule of which at least one is reacted with a hydrophilic oligomeric ethylene glycol containing a single isocyanate reactive end group and the remainder of the isocyanate groups are reacted with a hydroxy(meth)acrylate or (meth)acrylic acid so that there are, on average, at least two (meth)acrylate or (meth)acrylamide groups per average molecule of the preferred polyurethane(meth)acrylate or (meth)acrylamide.

Synthesis of these polyurethane(meth)acrylates or (meth)acrylamides starts with branched polyisocyanates. The preferred branched polyisocyanates which contain at least three isocyanate groups per molecule include a range of commercially available oligomers of diisocyanates, for instance, hexamethylene diisocyanate (HMDI), trimethylhexamethylene diisocyanate (TMHMDI), isophorone diisocyanate (IPDI), toluene diisocyanate (TDI), methylene di(phenylisocyanate) (MDI), tetramethyl xylyldiisocyanate (TMXDI), and mixtures thereof, with the most preferred polyisocyanate oligomers being based on HMDI and TMHMDI.

Further branching of the polyisocyanate (giving a higher average isocyanate functionality per molecule) can be obtained by reacting such commercially available polyisocyanates with fractional molar amounts of water or ammonia or other reactants which contain two or more isocyanate reactive groups such as alcohols, amines and carboxylic acids, either separately or in combination. Examples of suitable diols include ethylene glycol, 1,4-butane diol, 1,6-hexane diol, any of the dimethylol cyclohexane isomers, di-, tri-, and higher oligomers of ethylene glycol commercially available under the Carbowax trademark, trimethylolpropane (TMP), glycerin or other hydrophilic triols such as TPEG 990, also available under the Carbowax trademark, or hydrophobic polyols such as castor oil, and the like. Additional suitable polyols that increase branching (number of chain ends) include hydroxy(meth)acrylates containing more than one hydroxy group and at least one C═C functional group, particularly as exemplified by commercially available Laromer 8765 (BASF) or CN132 and CN133 (both from Sartomer), which also further serve to incorporate reactive C═C groups into the polyisocyanate. Suitable polyamines include ethylene diamine, diethylene triamine, triethylene tertraamine, and the like, and hydrazine or hydrazides (H₂NNHCO)ₙ—R where n is at least 2, urea, and the like. Useful carboxylic acid containing compounds that contain at least two COOH groups include succinic, fumaric, adipic, the three phthalic acid isomers, and ethylenediamine tetraacetic acid, among others. Compounds that contain mixtures of such isocyanate reactive groups include hydroxyethyl amines such as monoethanol amine and N-methyl ethanolamine (each of which have 2 reactive groups), diethanol amine and triethanol amine (each of which have 3 reactive groups). Compounds containing both acid and alcohol or amine functionality include for example lactic acid and glycine. Also suitable are the higher oligomeric polyether polyamines such as available under the Jeffamine trademark. To maintain relatively low molecular weights in these higher functional materials, the preferred isocyanate group to isocyanate reactive group molar ratio is greater than about 4 to 1, with greater than about 6 to 1 being more preferred, and greater than about 8 to 1 being most preferred, especially when reactants containing 3 or more isocyanate reactive groups are used to increase chain branching. Branched polyisocyanates can also be prepared directly from the reaction between molar excesses of diisocyanates with reactants containing 3 or more isocyanate reactive groups such as those described above.

The most preferred components from which to build hydrophilic side chains into the preferred highly branched polyurethane acrylates include oligomeric ethylene glycol and related polyethers, preferably possessing a single free isocyanate reactive end group, which compounds can be represented as HX—(CH₂CH₂O)ₙ—R₁ where X═O, S, NH or NCH₃ and R₁ contains 4 or fewer carbon atoms, particularly C₁-C₄ alkyl or acetate (CH₃CO—), and more particularly acrylate (H₂C═CHCO—) or methacrylate (H₂C═CCH₃CO—), and where n≧4, preferably where n≧8, and most preferably where n≧12. Other related hydrophilic components are either random or block copolyethers based on ethylene oxide or its equivalent copolymerized with 1,2- or 1,3-propylene oxide or their functional equivalents or 1,2-, 1,3-, 2,3- or 1,4-butylene oxide or their functional equivalents, where at least 50 mol % of the ether units contain only two carbon atoms and the isocyanate reactive end group is preferably alcohol or amine and which have molecular weights exceeding about 350 daltons.

Suitable hydrophilic modification of the branched polyisocyanates from which the participating polyurethane(meth)acrylate oligomers and resins are made is achieved by reacting sufficient moles of the hydrophilic segments to provide an average of at least one mole of isocyanate reactive groups per molecule of polyisocyanate in order to provide at least one such hydrophilic modifying segment per average polyisocyanate molecule. As the molecular weight of the hydrophilic modifying segment increases, the weight percent of hydrophile required to provide one such segment per polyisocyanate molecule will necessarily increase. Also, as the average number of isocyanate groups per polyisocyanate molecule increases, the average number of hydrophilic side chain segments per molecule should also increase such that there is at least about one hydrophilic side chain for every 3 isocyanate groups present in the core polyisocyanate. It will be apparent to one skilled in the art that this guideline is only approximate and that it will vary as the structures of the hydrophilic segments and reactive functional groups and starting polyisocyanates vary across the wide range of choices available. Nevertheless, it is preferred that at least about 20 weight percent of the final branched participating polyurethane(meth)acrylate be derived from the hydrophilic segment, with at least 25 weight percent being more preferred, and at least 30 weight percent being most preferred.

In many instances, the polyisocyanates are sufficiently hydrophobic to drive micro phase separation in the cured films, but in other instances, it may be desirable to enhance their hydrophobicity. Such modification may be done in a separate reaction step from the hydrophilic modification, either prior to or subsequent to the hydrophilic modification, or it may be combined so both hydrophilic and hydrophobic groups are attached to the polyisocyanate core in a single reaction step. Suitable hydrophobic modification of the branched polyisocyanates from which the participating polyurethane(meth)acrylate oligomers or resins are made is achieved by reacting sufficient moles of the hydrophobic segments to provide an average of at least one mole of isocyanate reactive groups per molecule of polyisocyanate to provide at least one such modifying segment per average polyisocyanate molecule. As the molecular weight of the hydrophobic modifying segment increases, the weight percent of hydrophobe required to provide one such segment per polyisocyanate molecule will necessarily increase. Also, where desired, as the average number of isocyanate groups per polyisocyanate molecule increases, the average number of hydrophobic side chain segments per molecule should also increase such that there is at least about one hydrophobic side chain for every three isocyanate groups present in the original polyisocyanate. It will be apparent to one skilled in the art that this guideline is only approximate and that it will vary as the structures of the hydrophobic segments and reactive functional groups and starting polyisocyanates vary across the wide range of choices available. Nevertheless, it is preferred when hydrophobic modification is desired, that at least about 20 weight percent of the final branched participating polyurethane acrylate be derived from the hydrophobic group, with at least 25 weight percent being more preferred, and at least 30 weight percent being most preferred.

Free radical reactive (meth)acrylate or (meth)acrylamide end groups on the participating polyurethane oligomer or resin can be obtained by reaction of a polyisocyanate modified with hydrophilic and/or hydrophobic segments and possessing an average of at least 2 residual isocyanate groups on each of the so modified core polyisocyanate molecules with hydroxy (meth)acrylate materials such as hydroxyethyl-, hydroxypropyl- (linear or branched) and hydroxybutyl- (linear or branched) (meth)acrylates, or (meth)acrylic acid (which form (meth)acrylamide end groups with evolution of CO₂), or β-carboxyethyl acrylate, and other carboxylic acid functional (meth)acrylates, such as available as the reaction product from the reaction between cyclic carboxylic dianhydrides with hydroxy acrylates, exemplified by succinic anhydride and hydroxyethyl acrylate, or alcohols made from the reaction products of monoglycidyl ethers of cyclic, linear or branched alcohols, particularly hydrophobic alcohols such as cyclohexyl, lauryl or 2-ethylhexyl alcohols, or esters of hydrophobic acids such as neodecanoic (C₁₀), available commercially as Cardura E10 (Hexion) or Glydexx N10 (ExxonMobil), with (meth)acrylic acid. The most preferred end groups are acrylate, and the most preferred hydroxy acrylates are derived from hydrophobic glycidyl ethers or esters, particularly neodecanoic acid glycidyl ester with (meth)acrylate functional carboxylic acids, forming participating polyurethanes(meth)acrylate oligomers or resins.

The preferred spectator resins or polymers useful in this invention are either linear or branched (containing an average of at least two and preferably more than two end groups per molecule), and preferably contain hydrophilic segments within the branches, preferably near or at the ends of the branches, with the most preferred structures being highly branched. Mixtures of these spectator resins or polymers can be employed. These spectator resins or polymers do not substantially participate in the crosslinking or curing reactions which the reactive groups present in the low molecular weight reactive diluents undergo upon irradiation, thereby forming an interpenetrating polymer network consisting essentially of the spectator resins or polymers physically entangled and entrapped within the crosslinked network formed by the polymerized or cured reactive components, such components reacting by one or more than one mechanism, such as a combination of radical and cationic mechanisms, and generally consisting of a mixture of reactive components with a range of molecular weights.

The preferred spectator resins, polymers or copolymers have molecular weights sufficiently high to permit their effective physical entanglement within the polymerized reactive component network such that they are not readily extracted by contact with water or other liquids, but not so high as to render the compositions too high in viscosity when incorporating an effective amount of the polymer for convenient application to a substrate without extensive dilution of the formed coating compositions by water or reactive diluent. While it is understood that this standard will differ by polymer composition, class and architecture, it should be clear that molecular weights between about 3,000 and 80,000 daltons, preferably between about 4,000 and 60,000 daltons, and more preferably between about 4,000 and 30,000 daltons, will generally satisfy this functional definition.

The most preferred spectator resins or (co)polymers contain substantial percentages of hydrophilic chain segments that are formally derived from repeating units based on cyclic ethers containing from 3 to 5 ring atoms, with 5 ring atoms (tetrahydrofuran) being the least preferred, 4 ring atoms (oxetane) being preferred, and 3 ring atoms (glycidyl type epoxy) being most preferred, and which are commercially available under trade names like Jeffamine and Carbowax. Also preferred are so-called comb-branched resins or (co)polymers containing substantial percentages of structural components that are derived from repeating units based on the addition polymerization of oligo ethylene glycol mono(meth)acrylates, particularly those containing OH or methyl ether end groups, where the oligo ethylene glycol groups are comprised of from 1 to about 20 ethyleneoxy (—CH₂CH₂O—) repeat units, particularly where such hydrophilic monomers are copolymerized as blocks with substantially hydrophobic monomers such as mono(meth)acrylic esters including butyl methacrylate or nonyl acrylate, or styrene and its derivatives. Also useful are resins, polymers or copolymers that contain substantial percentages of chain segments derived from repeating units based on hydrolyzed or unhydrolyzed vinyl acetate (commercially available from several suppliers as vinyl alcohol-vinyl acetate or related acetal modified polymers such as polyvinyl formal or butyral or ethylene-vinyl alcohol copolymers); random or block acrylic copolymers based on hydrophobic monomers combined with a substantial weight fractions of linear or branched C₃-C₆ ω-hydroxyalkyl(meth)acrylate monomers, such as hydroxyethyl acrylate or hydroxypropyl methacrylate and the like, or other hydrophilic monomers such as hydrolyzed glycidyl(meth)acrylate, also known as glycerol mono(meth)acrylate, as well as monomers such as acrylamide, allyl alcohol and its lower alkyl ethers, including allyl glycidyl ether (where the allyl group has been incorporated into the backbone and the glycidyl ether portion is a chain substituent) and its hydrolysis(allyl glycerin) or other ring-opening reaction products, such as the reaction product of the glycidyl group with nucleophiles to form a ring opened (OH-containing) derivative, and lower alkyl vinyl ethers, particularly where the alkyl group is ethyl or methyl; acrylic or methacrylic acid, β-carboxyethyl acrylate, maleic anhydride and its half esters with alcohols containing 4 or fewer carbon atoms, 2-acrylamido-2-methylpropanesulfonic acid, vinyl sulfonate or phosphonate, dimethylaminoethyl(meth)acrylate, allyl amine, and diallyldimethyl ammonium chloride, among others. Further useful spectator resins, polymers or copolymers can be obtained from monomers such as glycidol, lower glycidyl ethers, especially oligo ethyleneglycol monoglycidyl ether, glycidyl formate, acetate or propionate, copolymers of cyclic ether or carbonate and vinyl ether monomers such as between tetrahydrofuran, oxetane, ethylene oxide or ethylene carbonate with methyl vinyl ether, copolymers of maleic anhydride and divinyl ether and derivatives thereof. It will be appreciated that all such hydrophilic copolymers as described above will be derived from about 30 to about 100 mole percent of hydrophilic monomers where the particular preferred (co)polymer compositions will depend on the overall coating composition, hydrophilic (co)polymer class, molecular weight, architecture, and solubility. Further useful spectator resins or polymers include hydrophilic polyurethanes such as made from polyisocyanates and ethylene glycol oligomers, as well as organic soluble polysaccharides such as hydroxyethyl and hydroxypropyl cellulose, carboxymethyl cellulose, mixed cellulose ether esters, organic soluble starch derivatives such as acrylamido starch, modified chitin and chitosan, as well as polyethylene imine and other cationic polymers such as used in papermaking and water treatment, other hydrophilic resins and polymers with hydroxyl numbers greater than about 80 such as copolymers of glycidyl ethers and water or diols, polyester polyols, and ethoxylated polyols such as glycerine, trimethylolpropane, pentaerythritol or sorbitol, or polyesters that have acid numbers greater than about 80 such as can be derived from polyesters, and the like.

In another preferred embodiment of the invention, the higher molecular weight components are reactive oligomers, i.e., having higher molecular weights than the reactive diluents, typically below about 5,000 daltons, and/or viscosities typically below about 15,000 cps at 25° C., and at least one reactive functional group per average molecule. Particularly useful oligomers contain on average more than about one reactive group per molecule, more preferably more than about 1.5 reactive groups per molecule, and most preferably more than about two reactive groups per molecule, such reactive groups being capable of curing by polymerizing or crosslinking, and preferably copolymerize at least in part with the functional groups present in the reactive diluents. The curing can be by more than one mechanism, such as a combination of radical and cationic mechanisms.

Oligomers which cure by radical initiated reactions include polyether polyacrylates, such as poly(ether amine)polyacrylates, which can be made by, for example, a Michael reaction between polyether polyamines, most preferably polyether diamines, such as available commercially under the trade name Jeffamine, with molar excesses of polyacrylate reactive diluents, most preferably diacrylate reactive diluents such as polyethyleneglycol diacrylate and hexanediol diacrylate, where the molar ratio of C═C to N—H is at least 1.1 to 1, preferably at least 1.5 to 1, and more preferably at least 2 to 1. The polyether structure in the polyether polyamine can be represented as —O-Q-O— where Q is a linear or branched C₂₋₄ alkyl, preferably C₂₋₃ and most preferably as C₂ alkyl, or combinations of these polyethers where at least 50 mol % of the component ether monomers is comprised of Q=—CH₂CH₂— and where the copolyethers may be random or block.

Further useful hydrophilic oligomers, which copolymerize by a free radical reaction mechanism with other C═C containing compounds, constitute the reaction products between maleic anhydride, maleic or fumaric acid, or lower alkyl esters of these acids, with polyether amines as defined above, or ethylene glycol oligomers with at least one —OH end group, i.e., H(O—CH₂CH₂)ₙ—OR where R is H or a group containing 4 or fewer carbon atoms, where on average n is at least 4, preferably where n is at least 8, and more preferably where n is at least 12, such that at least one such ethylene glycol oligomer is reacted per mole of maleic anhydride (or maleic or fumaric acid, or lower alkyl esters of these acids) to form the half ester or diester, or in the case where there are two —OH end groups per ethylene glycol oligomer, there are on average between 2 and 10 C═C groups per molecule derived from maleic or fumaric substructures, preferably between 2 and 8 such C═C groups, and more preferably between 2 and 6 such C═C groups.

Yet other suitable hydrophilic oligomers can be made from polyisocyanates, most preferably diisocyanates, reacted with hydrophilic hydroxy mono(meth)acrylates such as oligo ethyleneglycol mono(meth)acrylate, H(O—CH₂CH₂)ₙ—OC═OCR═CH₂ (R═H, CH₃), where on average n is at least 4, preferably at least 8, and more preferably at least 12, such preferred oligomers differing from the above described participant resins in that they are of lower molecular weight and contain no hydrophilic groups which do not also contain reactive polymerizable groups at or near the chain ends.

Still other particularly useful hydrophilic oligomers can copolymerize with both free radical and cationic reactive groups. Such oligomers are derived from the reaction between polyol polyglycidyl ethers such as ethylene, propylene or butylene glycol diglycidyl ethers, glycerin or trimethylolpropane triglycidyl ethers or sorbitol polyglycidyl ether, and (meth)acrylic functional acids such as (meth)acrylic acid, β-carboxyethyl acrylate, the half ester of maleic or succinic anhydrides from reaction with hydroxy acrylates like hydroxyethyl or hydroxypropyl acrylate, which form polyol(meth)acrylic esters that also contain at least one hydroxyl group per reactive C═C group. Related reactive oligomers that can copolymerize with both free radical and cationic reactive groups are made by reaction of sub-molar amounts of (meth)acrylic functional acids with polyol polyglycidyl ethers such that the reaction products contain C═C, glycidyl ether and hydroxyl groups. Commercially available materials which meet these criteria are exemplified by Laromer 8765 (BASF), CN132 and CN133 (Sartomer).

Further useful oligomers are those which participate in cationic initiated cure reactions. Such oligomers include polyols, particularly exemplified by polyols which are made by chain extension by reaction of polyol or polyacid cores with cyclic ethers containing 3, 4 or 5 ring atoms, separately or in mixture, where structures derived from cyclic ethers containing 3 ring atoms are preferred, particularly ethoxylated polyols, and where on average between about 0.1 and 12 moles of cyclic ether are reacted per mole of core polyol hydroxyl groups or polyacid carboxylic acid groups. Such polyols include ethylene, propylene, or butylene glycols, glycerin, trimethylolpropane, pentaerythritol, sorbitol, castor oil and the like, and the polyacid cores are from succinic acid or anhydride, phthalic or trimelitic acid or anhydride and citric acids, among others. Such chain extended polyol components will not homopolymerize and so should be used in combination with other cationically reactive functional groups such as strained ring cyclic ethers, cyclic carbonates, or vinyl ethers. More particularly, polyols that either also or exclusively contain cyclic ether substructures, particularly cyclohexene oxide substructures available under the Cyracure trademark or oxetane substructures available under the Aron trademark; as well as polyol polyglycidyl ethers such as ethylene glycol, glycerin, trimethylolpropane and sorbitol polyglycidyl ethers available under the Erysis trademark; particularly which may also contain hydroxyl groups and, which are optionally chain extended by reaction with ethylene or propylene oxide. Also useful are oligomers containing vinyl ether substructures.

Compositions comprised of reactive diluents and oligomers may advantageously have low viscosities before the addition of much water, so they can readily saturate porous substrates and cure at high web speeds. Due to their potential for very high crosslink densities, they can provide excellent durability and strength at low film weights. For example, low viscosity compositions that can form the breathable coatings of this invention can be obtained by combining water with a major portion consisting of a polyethyleneglycol diacrylate, β-carboxyethyl acrylate and dimethylaminoethyl acrylate, the latter two components with complimentary incipient charge centers preferably being used in equimolar amounts, combined with a lesser portion of (ethoxylated)trimethylolpropane triacrylate added for increased crosslink density and durability.

The compositions of this invention, especially those which contain larger proportions of oligomers, resins, or polymers, and which are therefore of higher viscosity, can be diluted with higher amounts of water in order to reduce viscosity and facilitate application to the substrate, which coated substrates are then exposed to high energy radiation such as from ultraviolet light or electron beam sources or possibly by exposure to a high frequency plasma discharge such as corona treatment, for coating cure without prior drying or purposeful removal of a substantial amount of the water. In the case of a free radical cure under exposure to ultraviolet radiation, such coating compositions generally require addition of components referred to as free radical photoinitiators which interact with the incident ultraviolet radiation to generate the initiating radical species. In the case of a cationic cure, such coating compositions generally require addition of components referred to as cationic photoinitiators which interact with the incident high energy radiation and generate the initiating cationic species and may require supplemental heating after exposure to facilitate cure in compositions which contain added water. In the case of dual cure systems, initiators appropriate for the type of chemistry and irradiation source are included. Typically, photoinitiators will be used at about 0.5-5% based on the total weight of the water-free, liquid portion of the composition. Also typically, the photoinitiators will be soluble in at least one of the major constituents of the composition.

These compositions can optionally include other additives as typically used in coatings applications, such as colorants which can be dyes or pigments, flow control agents, leveling agents, wetting agents, stabilizers, rheological modifying agents, plasticizers, and preservatives such as polymerization inhibitors, and the like to enhance specific attributes of the liquid and/or cured product, such as in application, performance, appearance and the like. Any conventional material or combinations of materials can be employed, including additives such as pigments and rheology modifiers that exist within the uncured liquid compositions as one or more separate solid dispersed phases.

The nature of the substrate coated is not limited. It can be monolithic or porous, flat or shaped, rigid or flexible, a woven or non-woven fabric, etc. Likewise, any convenient method of coating the substrate with the liquid coating composition, such as for instance, spray coating, doctor blade coating, dip coating, direct and offset coating, and the like, can be used. Once applied, the coating is cured by application of high energy radiation to the coating material in the conventional fashion using ultraviolet or electron beam emitters without prior drying or purposeful removal of a substantial amount of water. The resulting coated substrates can be cut and shaped into useful articles directly, such as disposable surgical gowns or personal hygiene items such as diapers, or by incorporation into other articles, such as liners for durable protective garments.

In order to further illustrate the invention, various non-limiting examples are set forth below. In these, as well as throughout the rest of this specification and claims, all parts and percentages are by weight and all temperatures are in degrees Centigrade, unless otherwise stated.

### EXAMPLES 1-7

### Synthesis of Branched Participating Oligomers and Resins from Polyisocyanates

Into a reactor fitted with a mechanical stirrer, a dip tube for air sparge, an inlet for maintaining a N₂ blanket, and a temperature probe was added Desmodure N100 (a commercial HMDI-based polyisocyanate with an average of 3.8 NCO groups per molecule), polyethyleneglycol monomethyl ether (Carbowax MePEG 350, average n≈8, or 550, average n≈12) and 0.20 wt % of a free radical inhibitor. The mass was mixed at ambient temperature until homogeneous after which time a urethane catalyst was added. After the peak exotherm temperature was reached, heat was applied to maintain the reaction at about 70° C. until no more change was observed in the NCO peak (by attenuated total reflectance FTIR at 2272 cm⁻¹), which occurred within about 1 hour. To the intermediate polyisocyanate cooled to below 30° C., a 3 mol % excess of a hydroxy functional acrylate monomer (either hydroxyethyl acrylate—HEA—or ACE, the reaction product of acrylic acid with neodecanoic acid glycidyl ester as Cardura N10, Hexion) and 0.20 wt % of another free radical inhibitor were then added. After the peak exotherm temperature was reached, heat was applied to maintain the reaction at about 70° C. until the NCO peak in the FTIR disappeared, which took about 7 more hours. Reactants and amounts used are summarized in Table 1.

### EXAMPLES 8-11

### Synthesis of Branched Participating Oligomers and Resins from Diisocyanates and Polyols

Into a reactor fitted with a mechanical stirrer, a dip tube for air sparge, an inlet for maintaining a N₂ blanket, and a temperature probe is added hexamethylene diisocyanate, a polyol (TMP=trimethylolpropane, HO(EG)₆A=hexaethylene glycol monoacrylate, TPEG 990=glycerin[(EG)₇OH]₃), and 0.20 wt % of a free radical inhibitor. The mass is mixed at ambient temperature until homogeneous after which time a urethane catalyst is added. After the peak exotherm temperature is reached, heat is applied to maintain the reaction at about 70° C. until no more change is observed in the NCO peak (by attenuated total reflectance FTIR at 2272 cm⁻¹). To the intermediate polyisocyanate cooled to below 30° C., a 3 mol % excess of a hydroxy functional acrylate monomer and 0.20 wt % of another free radical inhibitor are then added. After the peak exotherm temperature is reached, heat is applied to maintain the reaction at about 70° C. until the NCO peak in the FTIR disappears. Reactants and amounts are summarized in Table 2.

TABLE 1

| | | | | | | | Hydroxy | | | 90% less |
|---|---|---|---|---|---|---|---|---|---|---|
| | Wt % | Wt % | Wt % | MePEG | | | acrylate | Peak | | than |
| | MePEG | MePEG | Des | OH/NCO | Wt % | Wt % | OH/NCO | Molecular | PD | Molecular |
| Resin | 550 | 350 | N100 | equiv ratio | ACE | HEA | equiv ratio | Wt | (Mw/Mn) | Weight |
| 1 | 35.40 | — | 31.32 | 0.39/1.00 | 32.85 | — | 0.64/1.00 | 2,530 | 1.45 | 10,110 |
| 2 | — | 25.91 | 35.94 | 0.39/1.00 | 37.71 | — | 0.64/1.00 | 2,990 | 1.30 | 10,650 |
| 3 | 25.98 | — | 32.84 | 0.27/1.00 | 40.75 | — | 0.75/1.00 | 2,460 | 1.32 | 10,090 |
| 4 | 40.58 | — | 30.48 | 0.46/1.00 | 28.51 | — | 0.57/1.00 | 2,330 | 1.57 | 10,180 |
| 5 | 49.45 | — | 37.16 | 0.46/1.00 | — | 12.96 | 0.57/1.00 | 2,250 | 1.56 | 8,300 |
| 6 | — | 30.34 | 35.75 | 0.46/1.00 | 33.48 | — | 0.57/1.00 | 2,680 | 1.48 | 11,990, |
| 7 | — | 38.52 | 45.41 | 0.46/1.00 | — | 15.64 | 0.57/1.00 | 1,440 | 1.87 | 7,830 |

TABLE 2

| | HMDI | | | Polyol | Hydroxy | | | Resin |
|---|---|---|---|---|---|---|---|---|
| Resin | Wt % | Polyol | Wt % | OH/NCO | Acrylate | Wt % | OH/NCO | C═C |
| Number | Used | Used | Used | Ratio | Used | Used | Ratio | meq/g |
| 8 | 22.6 | TMP | 4.4 | 0.50/1.00 | HO(EG)₆A | 50.0 | 0.52/1.00 | 1.75 |
| 9 | 23.6 | CN133 | 24.2 | 0.50/1.00 | HO(EG)₆A | 52.2 | 0.52/1.00 | 2.81 |
| 10 | 26.1 | Castor Oil | 53.1 | 0.50/1.00 | HEA | 20.8 | 0.52/1.00 | 1.55 |
| 11 | 26.6 | TPEG 990 | 52.2 | 0.50/1.00 | HEA | 21.2 | 0.52/1.00 | 1.58 |

### EXAMPLES 12-15

### Coatings Formulated with Reactive Diluents, Participating Oligomers and Resins

Resin 4 from Table 1 (80 parts) was combined with 20 parts of trimethylolpropane triacrylate (TMPTA) and water (5 parts) to make a single phase solution. The solution was coated onto paper and cured by e-beam (100 kV, 3 Mrad). The cured composition exhibited good MEK and excellent water resistance. The same composition was combined with TMPTA and water (75/25/5) and coated onto style 306A filament nylon 6.6 semidull taffeta fabric (Testfabrics, Wilkes-Barre, Pa.) at three different coating weights and cured. The produced films at 53.6, 43.8 and 35.4 g/m² provided MVTR values of 457, 537 and 627 g/m²/day measured at 37.8° C. and 90% RH.

Equal weights of resins 9 and 11 from Table 2 (70 parts) are combined with 20 parts of TMPTA, 10 parts of an equimolar mixture of β-carboxyethyl acrylate and dimethylaminoethyl acrylate, and water (5 parts) to make a single phase solution. The solution is coated onto paper and style 306A filament nylon 6.6 semidull taffeta fabric (Testfabrics, Wilkes-Barre, Pa.) and cured by e-beam (100 kv, 3 Mrad) providing a durable and breathable coating.

### EXAMPLES 16-21

Single phase solutions are made by repeating the Example 8 but substituting resins 1-3 and 5-7 for resin 4. The solutions are coated onto paper and cured by e-beam (100 kV, 3 Mrad). Resin 3 formulated at 80 wt % with 20 wt % PEG200DA and coated onto style 306A filament nylon 6.6 semidull taffeta fabric (Testfabrics, Wilkes-Barre, Pa.) at 37.3 g/m² and exhibited MVTR value exceeding 600 g/m²/d at 72% RH and 25° C. when cured.

### EXAMPLES 22-23

### Coatings Formulated with Reactive Diluent and a Spectator Resin

A single phase solution was made by combining polyethylene glycol 4000 (12 parts, Dow) Laromer 8765 (28 parts, BASF) and water (3 parts). When coated onto paper and cured by e-beam (100 kV, 3 Mrad), the cured composition (20 g/m²) exhibited good MEK and water resistance (20 and 30 rubs, respectively). When coated onto style 306A filament nylon 6.6 semidull taffeta fabric (Testfabrics, Wilkes-Barre, Pa.) and similarly cured, it yielded a film at 36.6 g/m² which provided an MVTR value of 1,134 g/m²/day at 37.8° C. and 90% RH.

### EXAMPLES 24-27

Coatings were formulated as described in the table and tested for MVTR. The large increase in MVTR value when the amount of PEG was increased from 20 to 30 wt % is interpreted as transformation of the discontinuous hydrophilic phase to a continuous microphase within the cured film.

TABLE 2

| | Weight Percent | | | |
|---|---|---|---|---|
| Sample | Laromer | | Film wt | MVTR |
| Number | 8765 | PEG 4000 | g/m² | g/m²/day |
| 1 | 100 | 0 | 37.5 | 291 |
| 2 | 90 | 10 | 38.1 | 171 |
| 3 | 80 | 20 | 37.3 | 211 |
| 4 | 70 | 30 | 36.6 | 1,134 |

### EXAMPLE 28

### Dual Cure Coating Formulated with Reactive Diluents and Oligomers

A single phase solution is made by combining 25 parts each of TPEG 990 (polyethylene glycol triol, Dow), Laromer 8765 (BASF), TMPTA, and Erysis GE-30, (CVC Specialty Chemicals), 3 parts of Cyracure 6974 cationic photoinitiator (Dow), and 10 parts of water. The solution is coated onto paper and style 306A filament nylon 6.6 semidull taffeta fabric (Testfabrics, Wilkes-Barre, Pa.) and cured by e-beam (100 kV, 3 Mrad) providing a durable and breathable coating.

### EXAMPLES 29-37

### Coatings Formulated with Reactive Diluents and Oligomers

Four cationic UV curable single phase solutions were formulated from Cyracure 6105 (41 parts, cycloaliphatic epoxy), oxetane alcohol (33 parts), water (13 parts), Cyracure 6974 (3 parts, cationic photoinitiator) and 9 parts of either Erisys EDGE (ethyleneglycol diglycidyl ether) or Erisys GE-30 (trimethylolpropane triglycidyl ether). When coated onto paper and cured by UV (300 W/in², 100 m/sec), all compositions exhibited excellent MEK and water resistance (more than 50 rubs at a film weight estimated at less than about 10 g/m². When coated onto style 306A filament nylon 6.6 semidull taffeta fabric (Testfabrics, Wilkes-Barre, Pa.) and similarly cured, they yielded films which provided MVTR values exceeding 500 g/m²/day at 25° C. and 50% RH.

Various changes and modifications can be made in the invention without departing from the spirit and scope thereof. The embodiments set forth were intended to illustrate the invention and not to limit it.

What is claimed is:

1. A method of forming a durable, breathable energy curable coating on a substrate which comprises applying to a substrate a single phase liquid coating composition comprising water and a high energy curable component which contains at least one hydrophilic segment and at least one hydrophobic segment and which when cured by exposure to high energy radiation forms a breathable, liquid water resistant and durable monolithic solid film, wherein said film comprises micro phase separated hydrophilic and hydrophobic phases.

2. The method of claim 1, wherein the coated substrate is subjected to high energy curing to form a breathable, liquid water resistant and durable monolithic solid film.

3. The method of claim 2, wherein water content of the coating composition does not exceed about 25 weight percent, the combined concentration of all energy curable groups is greater than about 1.5 millimoles per gram of the liquid portion of the coating composition on a water-free basis, and high energy curing is applied to the composition to form a solid film having a water vapor transmission rate of at least 500 g/m²/day at film weights of about 45 g/m² or less.

4. The method of claim 3, wherein the water content of the coating composition is about 3 to 15 weight percent.

5. The method of claim 3, wherein the combined concentration of all energy curable groups is greater than about 2.0 millimoles per gram of the liquid portion of the coating composition on a water-free basis.

6. The method of claim 3, wherein the combined concentration of all energy curable groups is greater than about 2.5 millimoles per gram of the liquid portion of the coating composition on a water-free basis.

7. The method of claim 3, wherein the high energy curing is ultraviolet or electron beam curing, the water content of the coating composition is about 1 to 20 weight percent, and the high energy curable component comprises a combination of materials having different molecular weights.

8. The method of claim 7, wherein the high energy curable component combination contains at least two interpolymerizable materials.

9. The method of claim 7, wherein the high energy curable component combination comprises material which does not interpolymerize with another member of the combination.

10. The method of claim 9, wherein the high energy curable component combination contains material which does not homopolymerize.

11. The method of claim 7, wherein the high energy curable component combination contains at least one reactive diluent which is a material having a molecular weight up to about 2,000 daltons or a viscosity up to about 1,000 centipoises, or both.

12. The method of claim 11, wherein the reactive diluent has a molecular weight up to about 700 daltons or a viscosity up to 500 cps, or both, and more than one and up to four curable groups per molecule.

13. The method of claim 12, wherein each curable group is selected from the group consisting of acrylate, methacrylate, allyl, three membered ring cyclic ether, four membered ring cyclic ethers, cyclic carbonate, vinyl ether, and conjugated C═C groups.

14. The method of claim 13, wherein the reactive diluent is selected from the group consisting of polyethyleneglycol di(meth)acrylate, polypropylene glycol di(meth)acrylate, hexanediol di(meth)acrylate, ethoxylated or propoxylated hexanediol di(meth)acrylate, neopentyl glycol di(meth)acrylate, ethoxylated or propoxylated neopentyl glycol di(meth)acrylate, trimethylolpropane tri(meth)acrylate, ethoxylated or propoxylated trimethylolpropane tri(meth)acrylate, glycerol tri(meth)acrylate, ethoxylated and propoxylated glycerol tri(meth)acrylate, pentaerythritol tri and tetra(meth)acrylate, ethoxylated and propoxylated pentaerythritol tri and tetra(meth)acrylates, diallyl phthalate, β-carboxyethyl acrylate, dimethylaminoethyl(meth)acrylate, alkyl diol diglycidyl ethers, glycerol and trimethylolpropane triglycidyl ether and their ethoxylated or propoxylated analogues, the reaction product of said glycidyl ether-containing compounds with acrylic or methacrylic acid, β-carboxyethyl acrylate or sorbic acid, diethyleneglycol divinyl ether and sorbate esters, and compounds containing one or more cycloalkene oxide, norbornene oxide or oxetane moieties.

15. The method of claim 13, wherein the curable coating material comprises at least one high energy curable material which interpolymerizes with the reactive diluent.

16. The method of claim 13, wherein the curable coating material comprises at least one high energy curable material which does not interpolymerize with the reactive diluent.

17. The method of claim 13, wherein the curable coating material comprises at least one component which does not homopolymerize.

18. The method of claim 13, wherein the curable coating composition contains a high energy curable material having a peak molecular weight up to about 5,000 daltons which is higher than the molecular weight of the reactive diluent and a viscosity below about 15,000 centipoises.

19. The method of claim 18, wherein the high energy curable composition comprises at least one material that contains both free radical and cationic reactive groups.

20. The method of claim 13, wherein the curable coating material contains a branched high energy curable component having a molecular weight which is higher than the molecular weight of the reactive diluent and which contains C═C curable groups in a preponderance of the branches.

21. The method of claim 18, wherein the higher molecular weight high energy curable material is a polyurethane poly(meth)acrylate.

22. The method of claim 21, wherein the polyurethane poly(meth)acrylate is the reaction product of a polyisocyanate and a hydroxy(meth)acrylate having at least one hydroxy group and at least one C═C group.

23. The method of claim 18, wherein the polyurethane poly(meth)acrylate has a peak molecular weight between about 1,000 and 12,000 daltons and contains at least 20% by weight of hydrophilic segments.

24. The method of claim 13, wherein the higher molecular weight high energy curable material is branched and contains hydrophilic segments in at least one branch.

25. The method of claim 13, wherein said high energy curable component comprises said reactive diluent and a hydrophilic polyether polyacrylate.

26. A durable breathable monolithic solid film, said film comprising micro phase separated hydrophilic and hydrophobic phases, and said film exhibiting a water vapor transmission rate of at least 500 g/m²/day at film weights of about 45 g/m² or less.

27. The durable breathable monolithic solid film of claim 26, wherein said film has a water vapor transmission rate of at least 1,000 g/m²/day at film weights of about 40 g/m² or less.

28. The durable breathable monolithic solid film of claim 26, wherein said film comprises a cured mixture of at least two high energy curable materials having different molecular weights.

29. The durable breathable monolithic solid film of claim 26, wherein said cured film comprises a cured mixture of at least one reactive diluent and a higher molecular weight high energy curable material, wherein said reactive diluent is a material having a molecular weight up to about 2,000 daltons or a viscosity up to about 1,000 centipoises, or both.

30. The durable breathable monolithic solid film 1 of claim 29, wherein the cured reactive diluent is a polymer of a monomer selected from the group consisting of polyethyleneglycol di(meth)acrylate, hexanediol di(meth)acrylate, ethoxylated trimethylolpropane tri(meth)acrylate, diallyl phthalate, 1,4-butanediol diglycidyl ether, trimethylolpropane triglycidyl ether, and the reaction product of said glycidyl ether-containing compounds with acrylic acid, β-carboxyethyl acrylate or sorbic acid, diethyleneglycol divinyl ether and hydroxyethyl sorbate.

31. The durable breathable monolithic solid film of claim 30, wherein the cured reactive diluent and a cured higher molecular weight high energy curable material are interpolymerized.

32. The durable breathable monolithic solid film of claim 30, wherein the cured higher molecular weight high energy curable material is a cured polyurethane poly(meth)acrylate.

33. The durable breathable monolithic solid film of claim 30, wherein the cured polyurethane poly(meth)acrylate contains at least 20% by weight of hydrophilic segments.

34. The durable breathable monolithic solid film of claim 30, wherein the cured reactive diluent and cured higher molecular weight high energy curable material are not interpolymerized.

35. The durable breathable monolithic solid film of claim 27, wherein the cured higher molecular weight high energy curable material is branched and contains hydrophilic segments in at least one branch.

36. The durable breathable monolithic solid film of claim 26, wherein the cured higher molecular weight high energy curable material comprises a polymer of an oligomer having a peak molecular weight up to 5,000 daltons, a viscosity below about 15,000 cps at 25° C. and at least one ultraviolet or electron beam curable group.

37. An article of which at least a part comprises the durable breathable monolithic solid film of claim 26.

38. The article of claim 37 which is a fruit or vegetable packaging.

39. A substrate coated with a durable breathable monolithic solid film thereon, said film comprising micro phase separated hydrophilic and hydrophobic phases, and said film exhibiting a water vapor transmission rate of at least 500 g/m²/day at film weights of about 45 g/m² or less.

40. The coated substrate of claim 39, wherein said film has a water vapor transmission rate of at least 1000 g/m²/day at film weights of about 40 g/m² or less.

41. The coated substrate of claim 39, wherein said film comprises a cured mixture of at least two high energy curable materials having different molecular weights.

42. The coated substrate of claim 39, wherein said cured film comprises a cured mixture of at least one reactive diluent and a higher molecular weight high energy curable material, wherein said reactive diluent is a material having a molecular weight up to about 2,000 daltons or a viscosity up to about 1,000 centipoises, or both.

43. The coated substrate of claim 42, wherein the cured reactive diluent is a polymer of a monomer selected from the group consisting of polyethyleneglycol di(meth)acrylate, hexanediol di(meth)acrylate, ethoxylated trimethylolpropane tri(meth)acrylate, diallyl phthalate, 1,4-butanediol diglycidyl ether, trimethylolpropane triglycidyl ether, and the reaction product of said glycidyl ether-containing compounds with acrylic acid, β-carboxyethyl acrylate or sorbic acid, diethyleneglycol divinyl ether and hydroxyethyl sorbate.

44. The coated substrate of claim 43, wherein the cured reactive diluent and a cured higher molecular weight high energy curable material are interpolymerized.

45. The coated substrate of claim 43, wherein the cured higher molecular weight high energy curable material is a cured polyurethane poly(meth)acrylate.

46. The coated substrate of claim 43, wherein the cured polyurethane poly(meth)acrylate contains at least 20% by weight of hydrophilic segments.

47. The coated substrate of claim 43, wherein the cured reactive diluent and cured higher molecular weight high energy curable material are not interpolymerized.

48. The coated substrate of claim 40, wherein the cured higher molecular weight high energy curable material is branched and contains hydrophilic segments in at least one branch.

49. The coated substrate of claim 39, wherein the cured higher molecular weight high energy curable material comprises a polymer of an oligomer having a peak molecular weight up to 5,000 daltons, a viscosity below about 15,000 cps at 25° C. and at least one ultraviolet or electron beam curable group.

50. An article of which a part comprises the coated substrate of claim 39.
